(19) United States
(12) Patent Application Publication
(10) Pub. No.: US 2022/0363836 A1
(43) Pub. Date: Nov. 17, 2022

(54) THERMALLY CONDUCTIVE SILICONE COMPOSITION AND THERMALLY CONDUCTIVE SILICONE MATERIAL

(71) Applicant: PANASONIC INTELLECTUAL PROPERTY MANAGEMENT CO., LTD., Osaka (JP)

(72) Inventors: Hiroshi YAMAMOTO, Osaka (JP); Keiichi KOMATSU, Osaka (JP)

(73) Assignee: PANASONIC INTELLECTUAL PROPERTY MANAGEMENT CO., LTD., Osaka (JP)

(21) Appl. No.: 17/772,018

(22) PCT Filed: Oct. 30, 2020
(86) PCT No.: PCT/JP2020/040941

§ 371 Date: Apr. 26, 2022

(30) Foreign Application Priority Data
Nov. 8, 2019 (JP) 2019-203193

(51) Int. Cl. C08G 77/04; C08K 3/22; H01L 23/373

(52) U.S. Cl. CPC C08G 77/04; C08K 3/22; H01L 23/3737; C08K 2003/2227; C08K 2201/001; C08K 2201/014

(57) ABSTRACT

A thermally conductive silicone composition contains a silicone component (A) and a tetradecahedral filler (B1).

### TECHNICAL FIELD

The present disclosure relates to a thermally conductive silicone composition and a thermally conductive silicone material.

### BACKGROUND ART

A thermally conductive material is disposed between an electric component, such as a transistor or a central processing unit (CPU) of a computer, and a heat radiator (heat sink) to transfer heat generated from an electronic/electric component to the heat radiator. Patent Literature 1 discloses a thermally conductive silicone rubber composition obtained by dispersing, in silicone rubber, a thermally conductive inorganic filler subjected to a surface process with a silane coupling agent.

### CITATION LIST

### Patent Literature

Patent Literature 1: JP H11-209618 A

### SUMMARY OF INVENTION

High integration or the like of electronic/electric components tends to more and more increase the amount of heat generated from the electronic/electric components. Moreover, mounting a plurality of electronic/electric components having different sizes on a single substrate requires efficient transferring of heat from each electronic/electric component via a thermally conductive material.

It is an object of the present disclosure to provide: a thermally conductive silicone composition capable of increasing the thermal conductivity of a thermally conductive silicone material; and a thermally conductive silicone material made from the thermally conductive silicone composition.

A thermally conductive silicone composition according to an aspect of the present disclosure contains a silicone component (A) and a tetradecahedral filler (B1).

A thermally conductive silicone material according to an aspect of the present disclosure is produced from the thermally conductive silicone composition and includes: a silicone resin matrix made from the silicone component (A); and the tetradecahedral filler (B1) dispersed in the silicone resin matrix.

### BRIEF DESCRIPTION OF DRAWINGS

FIG. 1 is a schematic sectional view of an electronic device according to an embodiment of the present disclosure.

### DESCRIPTION OF EMBODIMENTS

A thermally conductive silicone composition according to the present embodiment is adopted to prepare a thermally conductive silicone material. A thermally conductive silicone composition contains a silicone component (A) and a tetradecahedral filler (B1).

The silicone component (A) is, for example, reaction curable silicone rubber in liquid form or silicone gel. The silicone component (A) may be of a two-component type or a single-component type. The silicone component (A) contains, for example, a reactive organic silicon compound, such as organopolysiloxane, and a hardener, and optionally contains a catalyst. The hardener contains, for example, at least one of organohydrogen polysiloxane or organic peroxide. The catalyst is, for example, a platinum-based catalyst.

The tetradecahedral filler (B1) effectively reduces the thermal resistance of the thermally conductive silicone material. This is probably because particles of the tetradecahedral filler (B1) easily come into surface contact with each other, which is more likely to increase the transfer efficiency of heat between the particles. The tetradecahedral filler (B1) preferably contains a tetradecahedral alumina filler (b1). In this case, the tetradecahedral alumina filler (b1) is highly thermally conductive and can thus particularly effectively reduce the thermal resistance of the thermally conductive silicone material.

The thermally conductive silicone composition preferably further contains an octahedral filler (B2). In this case, the thermal resistance of the thermally conductive silicone material is particularly effectively reduced. This is probably because a combination of the tetradecahedral filler (B1) and the octahedral filler (B2) particularly easily cause surface contact of particles in the tetradecahedral filler (B1) and the octahedral filler (B2). The octahedral filler (B2) preferably contains an octahedral alumina filler (b2). In this case, the octahedral alumina filler (b2) is highly thermally conductive and can thus particularly effectively reduce the thermal resistance of the thermally conductive silicone material.

Each of the tetradecahedral alumina filler (bl) and the octahedral alumina filler (b2) is produced by calcining, for example, highly pure aluminum hydroxide in an atmosphere containing, for example, hydrogen chloride.

The volume ratio of the tetradecahedral filler (B1) and the octahedral filler (B2) in the thermally conductive silicone composition is preferably within a range from 100:0 to 50:50. In this case, the thermal resistance of the thermally conductive silicone material is particularly effectively reduced. The volume ratio is more preferably within a range from 95:5 to 60:40, and much more preferably within a range from 90:10 to 65:35.

Note that fillers that can be included in each of the tetradecahedral filler (B1) and the octahedral filler (B2) are not limited to the examples described above.

The tetradecahedral filler (B1) may be processed with a silane coupling agent. When the tetradecahedral filler (B1) is processed with the silane coupling agent, the tetradecahedral filler (B1) is easily dispersed satisfactorily in the thermally conductive silicone composition and in the thermally conductive silicone material, and thus, the thermal resistance of the thermally conductive silicone material is more likely to be reduced. The octahedral filler (B2) may also be processed with a silane coupling agent. When the octahedral filler (B2) is processed with the silane coupling agent, the octahedral filler (B2) is easily dispersed satisfactorily in the thermally conductive silicone composition and in the thermally conductive silicone material, and thus, the thermal resistance of the thermally conductive silicone material is more likely to be reduced.

The thermally conductive silicone composition may contain a silane coupling agent. Also in this case, the tetradecahedral filler (B1) is easily dispersed satisfactorily in the thermally conductive silicone composition and in the thermally conductive silicone material, and thus, the thermal resistance of the thermally conductive silicone material is more likely to be reduced.

The shape of each of the tetradecahedral filler (B1) and the octahedral filler (B2) can be checked with a scanning electron microscope (SEM).

The tetradecahedral filler (B1) preferably has an average particle diameter of greater than or equal to 1 μm and less than or equal to 100 μm. In this case, the thermally conductive silicone composition is easily satisfactorily moldable, and thus, the polyhedral filler is more likely to reduce the thermal resistance of the thermally conductive silicone material more effectively.

The octahedral filler (B2) preferably has an average particle diameter of greater than or equal to 1 μm and less than or equal to 100 μm. In this case, the thermally conductive silicone composition is easily satisfactorily moldable, and thus, the polyhedral filler is more likely to reduce the thermal resistance of the thermally conductive silicone material more effectively.

Note that the average particle diameter is a median diameter (D50) calculated from particle size distribution obtained by a dynamic light scattering method.

The tetradecahedral filler (B1) or a combination of the tetradecahedral filler (B1) and the octahedral filler (B2) preferably includes two or more kinds of particle groups different in average particle diameter. In this case, the viscosity of the thermally conductive silicone composition is less likely to be increased. Thus, both satisfactory fluidity of the thermally conductive silicone composition and low thermal resistance of thermally conductive silicone material are easily obtained. For example, the tetradecahedral filler (B1) or the combination of the tetradecahedral filler (B1) and the octahedral filler (B2) preferably contains a first particle group having an average particle diameter of greater than or equal to 50 μm and less than or equal to 100 μm and a second particle group having an average particle diameter of greater than or equal to 5 μm and less than or equal to 20 μm, and the volume ratio of the first particle group and the second particle group is preferably within a range from 6:4 to 9:1. The tetradecahedral filler (B1) or the combination of the tetradecahedral filler (B1) and the octahedral filler (B2) may further contain a third particle group having an average particle diameter of greater than or equal to 0.1 μm and less than or equal to 3 μm. In this case, the volume ratio of the first particle group to the second particle group is preferably within a range from 6:3 to 7:2, the volume ratio of the first particle group to the third particle group is preferably within a range from 6:1 to 7:1, and the volume ratio of the second particle group to the third particle group is preferably within a range from 3:1 to 2:1.

When the thermally conductive silicone material contains the octahedral filler (B2), one of the tetradecahedral filler (B1) or the octahedral filler (B2) may contain the first particle group, and the other of the tetradecahedral filler (B1) or the octahedral filler (B2) may contain the second particle group. Alternatively, one of the tetradecahedral filler (B1) or the octahedral filler (B2) may contain the first particle group and the second particle group, and the other of the tetradecahedral filler (B1) or the octahedral filler (B2) may contain the third particle group. Still alternatively, one of the tetradecahedral filler (B1) or the octahedral filler (B2) may contain the first particle group and the third particle group, and the other of the tetradecahedral filler (B1) or the octahedral filler (B2) may contain the second particle group. Yet alternatively, one of the tetradecahedral filler (B1) or the octahedral filler (B2) may contain the second particle group and the third particle group and the other of the tetradecahedral filler (B1) or the octahedral filler (B2) may contain the first particle group. It is particularly preferable that the tetradecahedral filler (B1) includes the first particle group and the second particle group, and the octahedral filler (B2) includes the third particle group.

When the thermally conductive silicone material contains no octahedral filler (B2), the ratio of the tetradecahedral filler (B1) to the sum of the thermally conductive silicone composition is preferably greater than or equal to 60 volume % and less than or equal to 90 volume %. When the proportion is greater than or equal to 60 volume %, the thermal resistance of the thermally conductive silicone material is more likely to be particularly reduced. When the proportion is less than or equal to 90 volume %, the thermally conductive silicone composition is more likely to have satisfactory fluidity, and the thermally conductive silicone material is more likely to be satisfactorily flexible. The proportion is more preferably greater than or equal to 65 volume % and less than or equal to 85 volume %, much more preferably greater than or equal to 70 volume % and less than or equal to 80 volume %.

When the thermally conductive silicone material contains the octahedral filler (B2), the ratio of the total of the tetradecahedral filler (B1) and the octahedral filler (B2) to the sum of the thermally conductive silicone composition is preferably greater than or equal to 60 volume % and less than or equal to 90 volume %. When the proportion is greater than or equal to 60 volume %, the thermal resistance of the thermally conductive silicone material is more likely to be particularly reduced. When the proportion is less than or equal to 90 volume %, the thermally conductive silicone composition is more likely to have satisfactory fluidity, and the thermally conductive silicone material is more likely to be satisfactorily flexible. The proportion is more preferably greater than or equal to 65 volume % and less than or equal to 85 volume %, much more preferably greater than or equal to 70 volume % and less than or equal to 80 volume %.

The thermally conductive silicone composition is preferably in liquid form at 25° C. The viscosity of the thermally conductive silicone composition at 25° C. is preferably less than or equal to 3000 Pa·s. In this case, the thermally conductive silicone composition can be satisfactorily moldable and is easily molded into the form of a film by using, for example, a dispenser. Moreover, the thermally conductive silicone composition is easily defoamed, and therefore, voids can be suppressed from being formed in the thermally conductive silicone material. Note that the viscosity is a value measured with an E-type rotating viscometer under a condition of 0.3 rpm.

The thermally conductive silicone composition may further contain a filler other than the tetradecahedral filler (B1) or the octahedral filler (B2). For example, the thermally conductive silicone composition may contain at least one type of particles selected from the group consisting of appropriate metal oxide particles other than the tetradecahedral filler (B1) or the octahedral filler (B2), metal nitride particles, metal carbide particles, metal boride particles, and metal free particles.

The thermally conductive silicone composition is prepared by, for example, kneading the components described above. When the silicone component (A) is of a two-component type, a thermally conductive silicone composition including a first agent containing a reactive organic silicon compound in the silicone component (A) and a second agent containing a hardener may be prepared, and the first agent and the second agent may be mixed with each other when used. In this case, the tetradecahedral filler (B1) and the octahedral filler B2) are at least contained in at least one of the first agent or the second agent.

When the thermally conductive silicone material is made from the thermally conductive silicone composition, for example, the thermally conductive silicone composition is molded into the form of a film by an appropriate method such as press molding, extrusion molding, or calendering. Molding the thermally conductive silicone composition into the form of a film with a dispenser is also preferable. Subsequently, the thermally conductive silicone composition in the form of a film is cured by being heated under a condition according to the composition thereof, thereby providing a thermally conductive silicone material in the form of a film.

Note that the forms of the thermally conductive silicone composition and the thermally conductive silicone material are not limited to the form of a film but may be any form. Moreover, when the silicone component (A) is of a cold-curing type, the thermally conductive silicone composition may be cured without being heated, thereby providing the thermally conductive silicone material. The thermally conductive silicone material includes: a silicone resin matrix made from the silicone component (A); and a polyhedral filler dispersed in the silicone resin matrix.

The thermally conductive silicone material contains the tetradecahedral filler (B1), and optionally contains the octahedral filler (B2), so that the thermally conductive silicone material is more likely to have low thermal resistance. This is probably because particles of the filler come into contact with each other in the thermally conductive silicone material as described above, thereby forming a pathway via which heat is transferable, and at this time, the particles easily come into surface contact with each other, which is more likely to increase the transfer efficiency of heat between the particles.

When the thermally conductive silicone material is receiving press pressure, the thermally conductive silicone material is more likely to have particularly low thermal resistance in a direction of the press pressure. This is probably because the particles of the filler easily come into contact with each other in the direction of the press pressure. In the present embodiment, the particles easily come into surface contact with each other as described above, and therefore, the thermal resistance is more likely to be particularly reduced by application of the press pressure, and thus, even low press pressure can reduce the thermal resistance.

The thermal resistance of the thermally conductive silicone material is reduced as described above, and therefore, in a state where thermally conductive silicone material is pressed with direct pressure under a condition of a press pressure of 1 MPa, the thermal resistance of the thermally conductive silicone material in the direction of the press pressure is preferably less than or equal to 0.8 K/W. In this case, the thermally conductive silicone material can exhibit excellent thermal conductivity and is more likely to efficiently transfer heat even with low press pressure. The thermal resistance is more preferably less than or equal to 0.7 K/W, much more preferably less than or equal to 0.6 K/W.

The Asker C hardness of the thermally conductive silicone material is preferably less than or equal to 40. The Asker C hardness is measured with, for example, Asker rubber durometer type C manufactured by KOBUNSHI KEIKI CO., LTD. When the Asker C hardness is less than or equal to 40, the thermally conductive silicone material has satisfactory flexibility and easily tightly adheres to a surface having various shapes such as a warped surface and a wavy surface. The Asker C hardness is more preferably less than or equal to 20. Moreover, the Asker C hardness is, for example, greater than or equal to 1. The low Asker C hardness is achieved by selection of the silicone component (A), selection of the particle size of each of the tetradecahedral filler (B1) and the octahedral filler (B2), selection of the ratio of each of the tetradecahedral filler (B1) and the octahedral filler (B2), and the like.

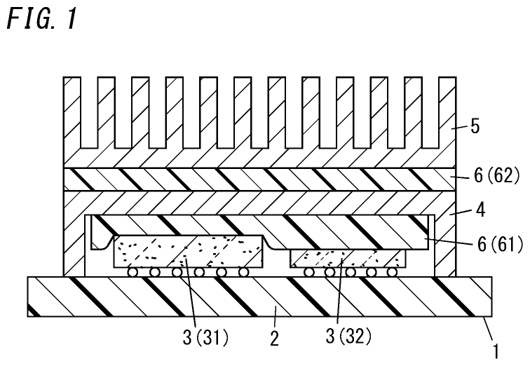

Examples of an electronic device including the thermally conductive silicone material will be described. An electronic device 1 shown in FIG. 1 includes a substrate 2, a chip component 3, a heat spreader 4, a heat sink 5, and two types of thermally conductive materials 6 (hereinafter referred to as TIM1 61 and TIM2 62). The chip component 3 is mounted on the substrate 2. The substrate 2 is, for example, a printed wiring board. The chip component 3 is, for example, a transistor, a CPU, an MPU, a driver IC, or memory but is not limited to these examples. A plurality of chip components 3 may be mounted on the substrate 2. In this case, the chip components 3 may have different thicknesses. The heat spreader 4 is mounted on the substrate 2 to cover the chip component 3. Between the chip component 3 and the heat spreader 4, a gap is provided, and in the gap, the TIM1 61 is disposed. On the heat spreader 4, the heat sink 5 is disposed, and between the heat spreader 4 and the heat sink 5, the TIM2 62 is disposed.

The thermally conductive silicone material in the present embodiment is applicable to both of the TIM1 61 and the TIM2 62. In particular, the TIM1 61 is preferably the thermally conductive silicone material according to the present embodiment. In this case, the thermally conductive silicone material may receive press pressure from the heat spreader 4. Thus, the particles of the polyhedral filler in the thermally conductive silicone material easily comes into contact with each other as described above, and therefore, particularly low thermal resistance of the thermally conductive silicone material is more likely to be realized.

Moreover, when the electronic device 1 includes a plurality of chip components 3 and the chip components 3 have different thicknesses, the dimension of a gap between a chip component 3(32) having a smaller thickness and the heat spreader 4 is greater than the diameter of a gap between a chip component 3(31) having a larger thickness and the heat spreader 4. Therefore, the press pressure applied to the TIM1 61 between the chip component 32 having a smaller thickness and the heat spreader 4 tends to be smaller than the press pressure applied to the TIM1 61 between the chip component 31 having a larger thickness and the heat spreader 4. Thus, the press pressure applied to the TIM1 61 is more likely to differ by location. However, the thermally conductive silicone material in the present embodiment contains the polyhedral filler as described above, and therefore, the thermal resistance is more likely to be particularly reduced by application of the press pressure. Therefore, even when press pressure applied to the thermally conductive silicone material differs by location, the thermally conductive silicone material is more likely to have low thermal resistance as a whole. Thus, when the TIM1 61 is the thermally conductive silicone material, the thermally conductive silicone material can efficiently transfer heat generated from the chip component 3 to the heat spreader 4, thereby easily fabricating the electronic device 1 having improved heat dissipation.

### EXAMPLE

More specific examples of the present embodiment will be described below. Note that the present embodiment is not limited to the examples described below.

1. Preparation of Composition

A silicone component and a filler were mixed, thereby preparing a composition. The type of the silicone component and the composition of the filler are as shown in Table 1, and details of the silicone component and the filler are as described below.
TES8553: Silicone resin manufactured by Toray Dow Corning Corp. Item number TES8553.
Filler 1: Tetradecahedral alumina filler having an average particle diameter of 42 μm.
Filler 2: Tetradecahedral alumina filler having an average particle diameter of 5 μm.
Filler 3: Spherical alumina filler having an average particle diameter of 40 μm.
Filler 4: Spherical alumina filler having an average particle diameter of 5 μm.
Filler 5: Octahedral alumina filler having an average particle diameter of 0.8 μm.

2. Evaluation

(1) Viscosity

The viscosity of the composition was measured under a condition of 0.3 rpm by using, as a measurement device, an E-type viscometer (model number: RC-215) manufactured by TOKI SANGYO CO., LTD.

(2) Asker C Hardness

The Asker C hardness of the composition was measured by using, as a measurement device, Asker rubber durometer type C manufactured by KOBUNSHI KEIKI CO., LTD. Moreover, as Comparative Example 4, a film having a thickness of 100 μm and made of indium was prepared, and the Asker C hardness of the film made of indium was also measured.

(3) Thermal Resistance

The composition was subjected to hot press under conditions of a heating temperature of 120° C. and a press pressure of 1 MPa for 30 minutes, thereby making a sample in the form of a sheet having a thickness of 100 μm. The sample was sandwiched between two plates made of copper, and the plates pressed the sample with direct pressure under a condition of a press pressure of 1 MPa. In this state, the thermal resistance of the sample in a direction of the press pressure was measured under a room temperature with DynTIM Tester manufactured by Mentor Graphics Corporation. Moreover, the thermal resistance of the film made of indium, which is Comparative Example 4, was also measured.

TABLE 1

| | Example | | | Comparative Example | | | |
|---|---|---|---|---|---|---|---|
| | 1 | 2 | 3 | 1 | 2 | 3 | 4 |
| Silicone Component | TES8553 | TES8553 | TES8553 | TES8553 | TES8553 | TES8553 | — |
| Filler 1 | 60 | 60 | 60 | — | — | — | — |
| (parts by volume) | | | | | | | |
| Filler 2 | 30 | 30 | 30 | — | — | — | — |
| (parts by volume) | | | | | | | |
| Filler 3 | — | — | — | 60 | 60 | 60 | — |
| (parts by volume) | | | | | | | |
| Filler 4 | — | — | — | 30 | 30 | 30 | — |
| (parts by volume) | | | | | | | |
| Filler 5 | 10 | 10 | 10 | 10 | 10 | 10 | — |
| (parts by volume) | | | | | | | |
| Filler Total | 100 | 100 | 100 | 100 | 100 | 100 | — |
| (parts by volume) | | | | | | | |
| Filler Content | 75 | 70 | 80 | 75 | 70 | 80 | — |
| (volume %) | | | | | | | |
| Viscosity | 1700 | 800 | 2300 | 1900 | 900 | 2500 | — |
| (Pa · s) | | | | | | | |
| Asker C Hardness | 15 | 10 | 20 | 15 | 10 | 20 | >50 |
| Thermal Resistance | 0.7 | 0.8 | 0.5 | 0.8 | 0.9 | 0.6 | 0.6 |
| (K/W) | | | | | | | |

As shown in the above result, when Example 1 and Comparative Example 1 are compared with each other, Example 2 and Comparative Example 2 are compared with each other, and Example 3 and Comparative Example 3 are compared with each other, using the tetradecahedral alumina filler in place of the spherical alumina filler reduces the thermal resistance.

1. A thermally conductive silicone composition comprising:
a silicone component (A); and
a tetradecahedral filler (B1).

2. The thermally conductive silicone composition of claim 1, wherein
the tetradecahedral filler (B1) contains a tetradecahedral alumina filler (1)1).

3. The thermally conductive silicone composition of claim 1, further comprising an octahedral filler (B2).

4. The thermally conductive silicone composition of claim 3, wherein
the octahedral filler (B2) contains an octahedral alumina filler (b2).

5. The thermally conductive silicone composition of claim 1, wherein
the thermally conductive silicone composition has a viscosity of less than or equal to 3000 Pa·s at 25° C.

6. A thermally conductive silicone material produced from the thermally conductive silicone composition of claim 1, the thermally conductive silicone material including
a silicone resin matrix produced from the silicone component (A), and
the tetradecahedral filler (B1) dispersed in the silicone resin matrix.

7. The thermally conductive silicone material of claim 6, wherein
in a state where the thermally conductive silicone material is pressed with direct pressure under a condition of a press pressure of 1 MPa, thermal resistance of the thermally conductive silicone material in a direction of the press pressure is less than or equal to 0.8 K/W.

8. The thermally conductive silicone material of claim 6, wherein
the thermally conductive silicone material has an Asker C hardness of less than or equal to 40.

9. The thermally conductive silicone composition of claim 2, further comprising an octahedral filler (B2).

10. The thermally conductive silicone composition of claim 9, wherein
the octahedral filler (B2) contains an octahedral alumina filler (b2).

11. The thermally conductive silicone composition of claim 2 wherein
the thermally conductive silicone composition has a viscosity of less than or equal to 3000 Pa·s at 25° C.

12. The thermally conductive silicone composition of claim 3 wherein
the thermally conductive silicone composition has a viscosity of less than or equal to 3000 Pa·s at 25° C.

13. The thermally conductive silicone composition of claim 4 wherein
the thermally conductive silicone composition has a viscosity of less than or equal to 3000 Pa·s at 25° C.

14. The thermally conductive silicone composition of claim 9 wherein
the thermally conductive silicone composition has a viscosity of less than or equal to 3000 Pa·s at 25° C.

15. The thermally conductive silicone composition of claim 10 wherein
the thermally conductive silicone composition has a viscosity of less than or equal to 3000 Pa·s at 25° C.

16. A thermally conductive silicone material produced from the thermally conductive silicone composition of claim 2, the thermally conductive silicone material including
a silicone resin matrix produced from the silicone component (A), and
the tetradecahedral filler (B 1) dispersed in the silicone resin matrix.

17. A thermally conductive silicone material produced from the thermally conductive silicone composition of claim 3, the thermally conductive silicone material including
a silicone resin matrix produced from the silicone component (A),
the tetradecahedral filler (B1) dispersed in the silicone resin matrix, and
the octahedral filler (B2) dispersed in the silicone resin matrix.

18. A thermally conductive silicone material produced from the thermally conductive silicone composition of claim 4, the thermally conductive silicone material including
a silicone resin matrix produced from the silicone component (A),
the tetradecahedral filler (B1) dispersed in the silicone resin matrix, and
the octahedral filler (B2) dispersed in the silicone resin matrix.

19. A thermally conductive silicone material produced from the thermally conductive silicone composition of claim 9, the thermally conductive silicone material including
a silicone resin matrix produced from the silicone component (A),
the tetradecahedral filler (B1) dispersed in the silicone resin matrix, and
the octahedral filler (B2) dispersed in the silicone resin matrix.

20. A thermally conductive silicone material produced from the thermally conductive silicone composition of claim 10, the thermally conductive silicone material including
a silicone resin matrix produced from the silicone component (A),
the tetradecahedral filler (B1) dispersed in the silicone resin matrix, and
the octahedral filler (B2) dispersed in the silicone resin matrix.
